(19) United States
(12) Patent Application Publication
(10) Pub. No.: US 2014/0140363 A1
(43) Pub. Date: May 22, 2014

(54) HIGH-YIELD HIGH-PRECISION DISTRIBUTED FEEDBACK LASER BASED ON AN ARRAY

(71) Applicant: Santur Corporation, Fremont, CA (US)

(72) Inventors: Bardia Pezeshki, Redwood City, CA (US); Gideon Yoffe, Fremont, CA (US)

(73) Assignee: Santur Corporation, Fremont, CA (US)

(21) Appl. No.: 13/903,823

(22) Filed: May 28, 2013

Related U.S. Application Data
(63) Continuation of application No. 10/794,785, filed on Mar. 4, 2004, now abandoned.
(60) Provisional application No. 60/452,174, filed on Mar. 4, 2003.

(51) Int. Cl. H01S 5/12; H01S 5/40

(52) U.S. Cl. CPC H01S 5/1246; H01S 5/4025
USPC 372/50.12

(57) ABSTRACT

A distributed-feedback laser with wavelength accuracy and spectral purity. An array of lasers with highly reflecting/anti reflecting facets is fabricated on a single chip with controlled variations, in for example laser gratings. A laser that best meets predetermined specifications is selected and configured for use.

### CROSS-REFERENCE TO RELATED APPLICATION

This application claims the benefit of U.S. Provisional Application No. 60/452,174, filed Mar. 4, 2003, which is hereby incorporated by reference as if set forth in full herein.

### BACKGROUND OF THE INVENTION

The present invention relates generally to wavelength control of a laser source in fiber optic communication systems, and more particularly to controlling distributed feedback lasers based in an array.

Lasers are commonly used as transmitters in fiber-optic communication systems. A typical system has very precise wavelength control and very high spectral purity. Because of manufacturing tolerances only a small fraction of fabricated lasers generally meet these tight requirements, so the cost of each in-specification laser may be high.

In a wavelength-division-multiplexed (WDM) transmission system, the wavelength of the transmitter generally should be controlled to within about 0.02 nm. This control generally can be accomplished by temperature control of the laser in conjunction with use of some form of a wavelength locking device. The variation of wavelength with temperature for a laser is approximately 0.1 nm per degree C. The design of the transmitter unit is simplified and its power consumption is minimized if the laser itself is selected to operate at the desired wavelength with no more than +/−2 degrees of temperature tuning. Therefore it is desirable that the laser should operate within 0.2 nm of the desired wavelength at some standard temperature.

Spectral purity is also preferred. Under continuous wave (CW) operation, the laser generally should operate with a single dominant wavelength. Side modes should often be suppressed by at least 30 dB, with many systems calling for 45 dB.

The laser also should be as efficient as possible, generating the desired optical power with the minimum electrical power input.

Since the refractive index of the material is a function of temperature, the optical pitch of the grating changes as the laser temperature changes, and thus the output wavelength is a sensitive function of temperature. For wavelength division multiplexing applications, where the output wavelength should be tightly controlled, the devices are generally packaged with a thermoelectric cooler that maintains a generally constant operating temperature for the chip.

A further complication of single frequency lasers in wavelength division multiplexed applications is that large numbers of different types of lasers generally must be made and stocked. For example in a 80 channel WDM system, 80 different part numbers are required for the lasers. Each part number must be made separately and inventoried. If a single laser chip could be used for a number of channels, it would greatly simplify the inventory and manufacturing costs.

Similarly, for modulated applications, an electro-absorption modulator is sometimes integrated on the same chip as the DFB laser, with the combination generally known as an EML (electroabsorption modulated laser). Both the optimum operating wavelength of the electroabsorption modulator (EA) and the lasing wavelength of the DFB change with temperature. So even in single wavelength networks, where the exact value of the output wavelength is not important, a thermoelectric cooler is often important to make sure that the DFB laser wavelength and the optimum wavelength of the EA are matched and don't drift as the case temperature changes.

In both discrete DFBs and EMLs, thermoelectric cooler adds cost, complexity and increases the required electrical power.

### BRIEF SUMMARY OF THE INVENTION

The yield can be increased significantly for very small additional cost using an array containing several laser elements fabricated on each chip. In one aspect of the invention, this is done with controlled variation of the grating from laser to laser, so that one of the laser elements will meet the specification. As an example, an array of twelve laser stripes with varying grating period and phase could be used to provide one or more lasers of the desired spectral purity that operate at the desired wavelength with a maximum temperature tuning of only a few degrees. This approach reduces the yielded cost of tightly specified DFB lasers. In the same vain, putting multiple lasers on the same chip allows the user to select and use only the most appropriate laser and eliminates the need to inventory and stock many different kinds of chips.

In one aspect the invention provides an increased yield distributed feedback (DFB) laser device, comprising a plurality of DFB lasers on a chip, each of the DFB lasers capable of lasing light, the light having spectral characteristics depending at least in part on a grating forming part of each DFB laser, wherein each grating differs by a controlled grating variation, and wherein only a single DFB laser is operationally configured to lase light.

In a further aspect the invention provides a process for manufacturing a laser chip with a laser output meeting predefined spectral specifications, comprising providing an array of lasers on a chip, the lasers differing by a controlled variation; testing the lasers in the array of lasers for at least one spectral characteristic; and identifying a one of the lasers in the array as a selected laser, the selected laser meeting a predefined spectral specification.

In a further aspect the invention provides a laser device with an integrated heating element comprising a plurality of lasers on a chip, each of the lasers capable of lasing light, the light having a wavelength dependent on temperature of the laser, and wherein a selected laser is operationally configured to lase light, the selected laser lasing light of a desired wavelength when the selected laser is above a predetermined temperature; and a heating element integrated with the plurality of lasers, the heating element heating the selected laser so as to maintain the selected laser above the predetermined temperature.

In a further aspect the invention provides a method of controlling wavelength of a laser array combined with an heating element, the method comprising measuring a physical parameter indicative of temperature of a selected laser; and applying heat to the selected laser if the physical parameter indicative of the temperature of the selected laser is below a predetermined value

In a further aspect the invention provides a laser with integrated electroabsorption modulator, comprising a laser; an electroabsorption modulator (EAM) coupled to the laser so as to receive light from the laser; a heating element thermally coupled to the EAM.

In a further aspect the invention provides for a electroabsorption modulated laser (EML) in a casing, with a laser section and an electroabsorption modulator section, the laser section being forward biased to provide light to the electroabsorption modulator section, the electroabsorption modulator section being reversed biased to modulate the light from the laser section, the electroabsorption modulator section being further equipped with a heating element comprising a resistive heater approximate the electroabsorption modulator section, a method to maintain wavelength registration between the laser section and the electroabsorption modulator section, the method comprising heating the electroabsorption modulator section using the heater, whereby wavelength registration between the laser and the electroabsorption modulator is maintained within a window.

These and other aspects of the invention are more fully appreciated upon review of this disclosure including the associated figures.

### BRIEF DESCRIPTION OF THE DRAWINGS

FIGS. 1A and 1B illustrate various views of a semiconductor chip with an array of substantially single frequency lasers in accordance with aspects of the invention.

FIG. 2 illustrates a laser array mounted to a submount with a single element of the laser array wirebonded to a contact of the submount.

FIG. 3 illustrates a flow diagram of one embodiment of a process of forming a laser in accordance with aspects of the invention.

FIG. 4 illustrates a cross-section view of a DFB laser including an etched grating.

FIG. 5 is an illustrative view of an array of DFB lasers with varying grating phase.

FIG. 6 is an illustrative view of an array of DFB lasers with varying grating period.

FIG. 7 is an illustrative view of an array of DFB lasers with varying grating phases and periods.

FIG. 8A illustrates simulated effects of grating phase for a HR/AR DFB laser on threshold current and output power.

FIG. 8B illustrates simulated effects of facet phase for a HR/AR DFB laser on lasing wavelength and gain margin.

FIGS. 9A-9C illustrate various views of a DFB laser, in accordance with aspects of the invention.

FIG. 10 illustrates a flow diagram of a further process of fabricating the DFB laser of FIG. 9B.

FIG. 11 illustrates one embodiment of a DFB laser array with heater stripes fabricated on top of the lasers.

FIG. 12A illustrates a top-view of another embodiment of a DFB laser array with heater elements.

FIG. 12B illustrates an electrical schematic of the DFB laser array with heater elements of FIG. 12A.

FIG. 13 illustrates an embodiment of controlling heater power of a DFB laser array.

FIG. 14 illustrates a voltage on a DFB laser as a function of temperature.

FIG. 15 illustrates a flow diagram of one embodiment of a process of controlling wavelength of a laser array in accordance with aspects of the invention.

FIG. 16 illustrates an embodiment of an EML with heater.

FIG. 17 illustrates a calculation of temperature contours around a laser with increased thermal resistance.

FIG. 18 illustrates an embodiment of both DFB lasers and an EML having separate integrated heaters.

FIG. 19 shows measured results on an EML where the heater power is used to provide constant device performance

### DETAILED DESCRIPTION

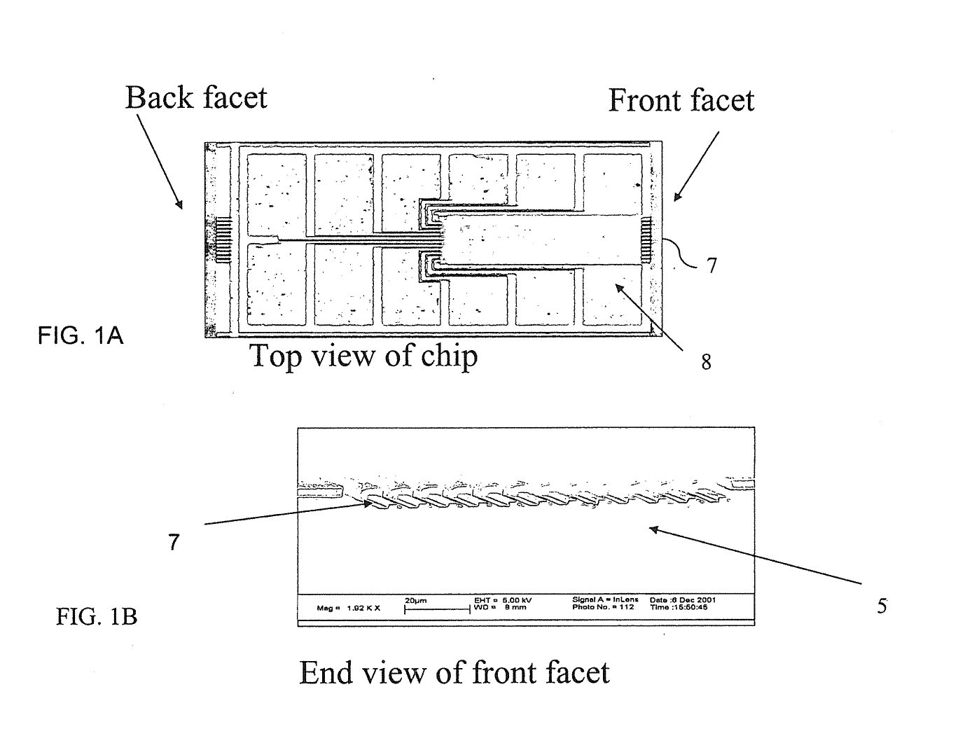

FIGS. 1A and 1B show an array of lasers on a semiconductor substrate. FIG. 1A illustrates a top view of an array of lasers on a semiconductor substrate. FIG. 1B illustrates an end view of a front facet of the array of lasers. In several embodiments the lasers are distributed feedback (DFB) lasers, and lase at approximately the same wavelength. The array of lasers comprises a number of independently addressable lasers or laser elements 7 formed on an InP substrate 5. Each laser has a separate contact pad 8 from which current is injected into the laser. When current is injected into the laser, the laser emits radiation with a specific wavelength. Although only twelve laser elements are shown in FIG. 1A, in varying embodiment different numbers of laser elements are used to form the array.

Lasers with different wavelengths may be formed using a number of techniques. These techniques include directly-written gratings with electron beam lithography, stepping a window mask during multiple holographic exposures, UV exposure through an appropriately fabricated phase mask, or changing the effective index of the mode of the lasers. Generally, for stable single mode characteristics, either a controlled phase shift is also included in the laser or a gain/loss coupling is used in the grating. The wavelength of such lasers can be accurately controlled through dimensional variables, such as stripe width or layer thickness, and varied across the array.

In aspects of the invention, slightly different wavelengths are assigned to each laser element in the array of lasers illustrated in FIGS. 1A and 1B. This is done, for example, by varying physical parameters of each laser element. The laser elements of the array are activated, preferably individually, and spectral characteristics of output light is measured. Generally, at least one of the laser elements has output light with desired spectral characteristics. Such a laser element is configured for operation by, for example, making the appropriate wiring connections for operational use.

An example of varying a laser physical parameter is varying a grating in a DFB laser. Thus, in some embodiments, the laser device of FIGS. 1A and 1B comprises a plurality of DFB lasers. The plurality of DFB lasers form an array of lasers on the laser device. Each of the DFB lasers is capable of lasing light, which has spectral characteristics depending at least in part on a grating of each laser.

A DFB laser with a constant grating period has a wavelength band of high reflectivity. Absent other factors the laser output often has two peaks, or modes, on either side of the band of high reflectivity. The laser may be caused to lase with a single peak by incorporating a phase shift in the grating, typically approximately one quarter of a grating period. The phase shift alters the nature of the cavity so that it tends to lase at a single wavelength, typically near the center of the wavelength band of high reflectivity. Such lasers are generally very stable and reproducible. In some instances, wavelength variations for a given design occur because of variations in the manufactured structure, but these can generally be held to within +/−0.5 nm or better in practice.

Accordingly, in accordance with some aspects of the invention, the lasers in the array of lasers of FIGS. 1A and 1B are DFB fabricated on a single chip. Each laser has a grating with a phase shift in the grating. The gratings in each of the lasers vary slightly in period from gratings of other lasers in the array, so that each laser is expected to lase at a slightly different wavelength. Of the lasers, the laser whose output has desired spectral characteristics is selected for use and, for example, wirebonded to a submount or otherwise electrically coupled to a drive signal.

In another embodiment, the lasers of FIGS. 1A and 1B are again DFB lasers fabricated on a single indium phosphide chip. The lasers have reflecting coatings applied to one or both facets of each laser. More particularly, in one embodiment one facet is made highly reflecting and the other facet is anti-reflecting, a so-called HR/AR design. This design has an advantage over the phase-shifted design in that almost all of the light generated is emitted from the anti-reflecting facet, whereas a phase-shifted laser emits similar power levels from each facet. The power emitted from the output facet of an HR/AR DFB laser is typically about 50% larger than that from one facet of a phase shifted laser.

However, in the HR/AR design the laser characteristics depend strongly on the precise phase relationship between the grating and the highly reflecting facet. As an aside, the phase relationship between the grating and the highly reflecting facet is sometimes referred to herein as the grating phase, the phase of the grating, or simply the phase. With such an understanding, and undoubtedly even without such an understanding, one of skill in the art will be able to differentiate between reference herein to a phase difference, or shift, between gratings of different lasers and a phase shift in the gratings of a single laser such as previously described with respect to the phase shifted laser. Returning to the discussion, the period of the grating is approximately 240 nm for a typical indium phosphide-based DFB laser operating near 1550 nm, and the facet is typically mechanically cleaved. It is therefore extremely difficult to control the phase relationship between the grating and the high-reflecting facet. The threshold current, output power, wavelength and the sidemode suppression ratio (SMSR) all depend on the phase.

Accordingly, in some embodiments of the laser array of FIGS. 1A and 1B the lasers in the array each have a grating which differs from gratings of other lasers of the array due to a variation, or shift, in phase with respect to the highly reflective facet. Each grating has a different phase, for example by longitudinally shifting the position of the grating with respect to other gratings, but has substantially the same period. In other embodiments, each laser has a grating with differing grating periods compared to gratings of other lasers, but substantially the same grating phase. In some other embodiments, both grating phases and grating periods are varied between lasers.

The spectral characteristics of the output of the lasers is characterized, and a particular laser of the array of lasers is selected. Preferably, the selected laser provides desired performance, generally with respect to predetermined specifications. The fabrication cost of such a chip is only slightly greater than that of a single laser, since the only significant addition to the fabrication process is the exposure of multiple gratings. Therefore the device allows a significant reduction in yielded component cost.

Providing an example with additional detail, for a 1550 nm DFB laser a specification may require a laser output with a wavelength within 0.07 nm at a defined temperature. The effective index of the mode can vary due to non-uniformity in the thickness of the layers, however, causing the wavelength of the laser to fluctuate. The phase of the grating between the different elements of the laser array may be varied, particularly in cases where the fluctuations are small. Accordingly, a 12 element array has a pitch of about 240 nm and each grating is longitudinally offset from its neighbor by about 20 nm. This provides a variation between the elements of about 0.1 nm. Thus at least one element of the array would be on-wavelength with an accuracy of 0.05 nm, which is within specification.

In another embodiment both the pitch (period) and the phase may be varied. In cases where index changes are larger, varying both pitch and phase may be particularly useful. Accordingly, an array of 12 elements is built with three different pitches and for each different pitch there are four different phases. For example the different pitches would correspond to the wavelengths of 1549, 1550, and 1551 nm, and the phases of the array would vary by about 60 nm. This translates to at least one element of the array being on-wavelength by +/−0.25 nm. Table I below shows an example of measured data for such a 12 element array. In this example, since the desired specification for the array is 1550+/−0.5 nm at 45 C and 200 mA and SMSR of greater than 40 dB, only laser number 6 satisfies the desired criteria.

TABLE I

| Laser | Wavelength (nm) | |
|---|---|---|
| number | at 200 mA | SMSR (dB) |
| 1 | 1548.67 | 12 |
| 2 | 1549.02 | 45 |
| 3 | 1549.14 | 48 |
| 4 | 1549.75 | 17 |
| 5 | 1549.7 | 12 |
| 6 | 1550.2 | 45 |
| 7 | 1550.8 | 45 |
| 8 | 1551.2 | 25 |
| 9 | 1551.9 | 48 |
| 10 | 1551.8 | 28 |
| 11 | 1552.1 | 53 |
| 12 | 1552.4 | 45 |

As previously mentioned multiple wavelength communication systems require the production of many different lasers, each with their own part number. Manufacturing many different lasers, stocking them, and providing spares is a complicated and costly effort. A laser array that had multiple functional lasers can be useful in reducing the amount of parts and inventory. For example, making an array of 24 lasers where lasers 1-12 correspond to table I and lasers 12-24 correspond to a different channel, attempting to fulfill a specification for 1560 nm wavelength would mean that a single chip could provide for two separate wavelengths. Thus a user would only stock this particular chip and use it either for the 1550 nm specification or the 1560 nm specification, depending on his need at the time. Accordingly, in some embodiments the array of lasers includes sets of lasers. Each set of lasers lases approximate a particular wavelength. The lasers in each set of lasers also include a controlled variation, such as a variation in phase or period. For such an array, a desired wavelength is determined. A set of lasers in the array is selected based on the desired wavelength. Of the set of lasers, a particular laser with desired spectral characteristics is selected and configured for operational use.

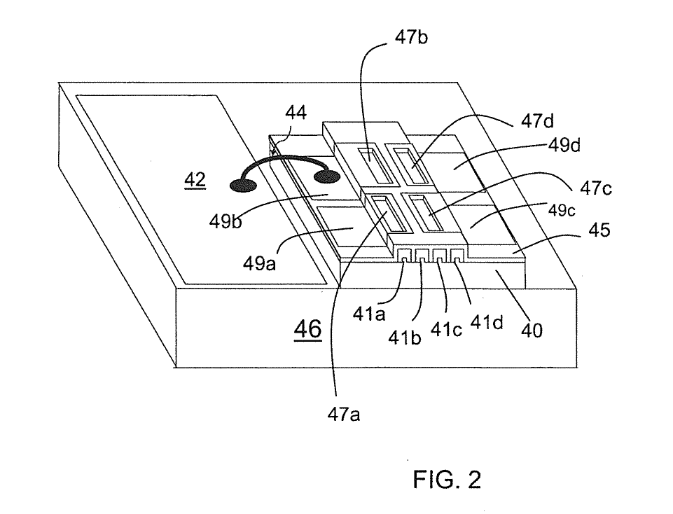

FIG. 2 illustrates a laser array fabricated on a single device with a single laser element bonded to a submount of the device. The device comprises four laser elements 41a-d arranged in parallel on a single laser chip 40. Although the laser chip 40 comprises only four laser elements, arrays of larger size can also be fabricated using the same topology of FIG. 2. The laser chip 40 is mounted on a submount, or substrate, 46. Each laser element 41a, 41b, 41c, 41d has a different grating buried in the ridge structure of the laser. The top of each ridge has a metallization layer providing a contact for injection of current into each laser. A dielectric layer 45 is applied to the upper surface of the laser chip. The dielectric layer 45 includes windows 47a-d on top of the ridge structure of each laser 41a-d, respectively. The windows provide access to the metallization layers on top of the ridges of each laser.

Still referring to FIG. 2, a second metallization layer is formed in such a fashion that ridge metallization accessible through each window is connected to a separate contact pad 49a-d. For example, the metallization accessible through window 47a is connected to the contact pad 49a. Similarly, the metallization accessible through window 47b is connected to the contact pad 49b, the metallization accessible through window 47c is connected to the contact pad 49c, and the metallization accessible through window 47d is connected to the contact pad 49d.

The submount 46 also includes a bond pad 42 for receiving an electrical coupling from the contact pads 49a-d of the lasers 41a-d via a wirebond 44. Generally the bond pad is coupled to only a single contact pad.

Thus, in the illustrated embodiment only one laser contact pad 49b is electrically coupled to the bond pad 42 via the wirebond 44. Current is applied from the bond pad 42 to activate a laser element 41b, connected to the coupled laser contact pad 49b. Thus, in this embodiment, only a single laser element is operationally configured to lase light. Preferably, the single laser is selected on the basis of meeting desired predetermined spectral specifications, such as wavelength, power, and SMSR.

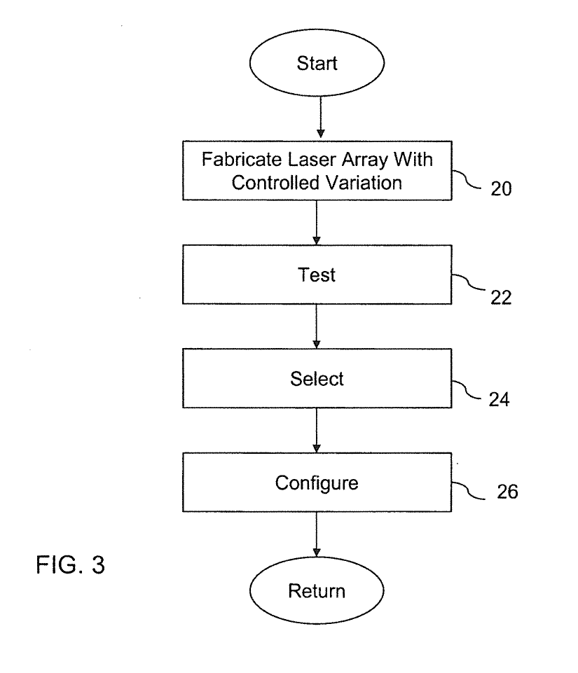

FIG. 3 illustrates a flow diagram of an embodiment of a process of forming a laser device based on an array of lasers. The laser device may be a laser device such as the laser device of FIG. 2. In some embodiments, the lasers are DFB lasers. In some other embodiments, the lasers are HR/AR DFB lasers. In block 20 of the process a laser array is fabricated on a chip. The lasers differ by a controlled grating variation, such as phase and/or grating period. Depending on the variation in index and wavelength and the desired predetermined specifications, phase or grating period alone may be varied, or both phase and grating period may be varied.

In block 22, the lasers are tested for spectral characteristics to determine their compliance with predefined spectral specifications, such as wavelength and/or SMSR. This specification generally depends on a particular system and intended use for the laser. For example, if the user requires a laser for a 1550 nm channel, the laser is tested against this wavelength, while if the channel is a 1560 nm channel in a WDM system, the criterion may change. In some embodiments, the lasers are tested with a probe card on a temperature controlled stage. The probe card provides contact to all the laser elements of the array. For example, when using the probe card, each laser is turned on, preferably one at a time, at an appropriate current level and the wavelength and the SMSR of the light output from the laser are measured with an optical spectrum analyzer.

In block 24, one of the lasers in the array is selected. Preferably the selected laser meets the predefined spectral specifications. The predefined spectral specifications, for example, may require a wavelength within a specified tolerance with a minimum SMSR. In some cases, however, the selected laser is merely the laser in the array of lasers that more closely meets at least some of the parameters of the specification than other lasers in the array.

In block 26 of the process, the selected laser is operationally configured to lase light. For example, the selected laser is wirebonded to a contact or bond pad on a submount. Application of an appropriate signal to the contact pad on the submount thereafter causes the laser to lase.

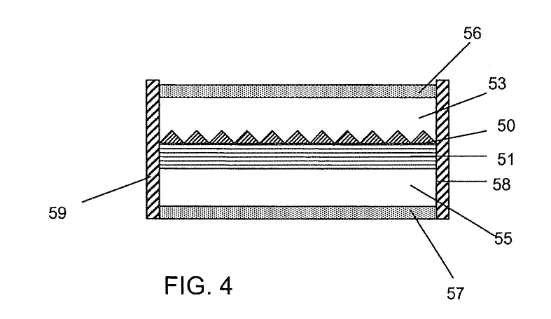

FIGS. 4-7 provide further illustration of array of lasers with controlled variation in gratings. FIG. 4 illustrates a simplified cross-section view of an etched grating of a DFB laser. The laser includes a waveguide with an active quaternary layer 51 having multiple strained quantum wells. An etched grating 50 on the active layer additionally forms part of the waveguide. The grating has a pitch, or period, calculated to cause the laser to lase at a predetermined wavelength proportional to the period of the grating.

Waveguide cladding is above and below the waveguide, with upper waveguide cladding 53 above the waveguide and lower waveguide cladding 55 below the waveguide. Metal contacts 56,57 are on top of the upper waveguide cladding and below the lower waveguide cladding, respectively. Facets 58,59 form opposing front and rear ends, respectively, of the laser. In some embodiments the rear facet is highly reflecting and the front facet is anti-reflective.

Light is generated within the waveguide when electrical current is passed through the device, generally by application of differing voltages to the metal contacts. The etched grating provides optical feedback at a wavelength proportional to the period of the grating. Additional feedback can be provided by reflection off of the end facets.

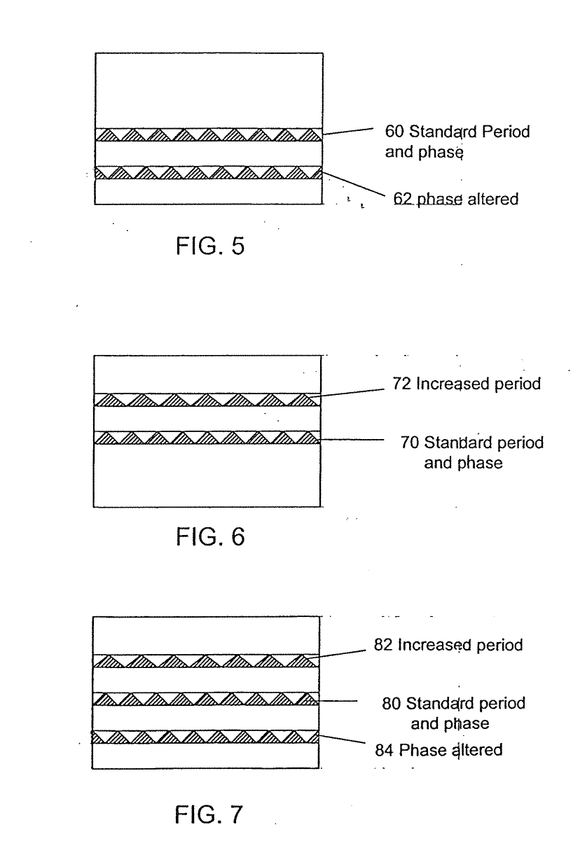

FIG. 5 is illustrative of an array of DFB lasers with varying grating phases. A first laser has a grating 60 having a first grating period and first grating phase. A second laser has a grating 62 having the first grating period, namely the grating of the second laser has the same period as the grating of the first laser. The grating of the second laser, however, differs in longitudinal position, or phase, from the grating of the first laser. As illustrated in FIG. 5, the gratings of the two lasers differ in phase by approximately one twelfth of a period. Such a phase difference between gratings for different lasers is particularly useful, for example, when the laser array includes 12 lasers. Since the position of the cleave forming the rear facet generally cannot be accurately controlled with respect to the grating, the exact phase of each element of the array cannot be predicted. However, by having a different longitudinal position on the gratings, the phase will be different between the various elements of the array. In the testing stage, the element with the proper phase can be selected and configured for use.

FIG. 6 is illustrative of an array of DFB lasers with varying grating periods. A first laser has a grating 70 having a first grating period and a first grating phase. A second laser has a grating 72 having the same grating phase, or longitudinal position, as the first laser. The grating of the second laser, however, has a different grating period than the grating of the first laser. As illustrated, the grating of the second laser has a slightly greater grating period than the first laser. In some embodiments, during manufacture a coating of photoresist is applied to the semiconductor wafer and the wafer is exposed to an interference pattern created by two laser beams. This technique offers fine control of the period. In such embodiments an electron beam pattern generator can be used, which can place features with accuracy on the order of a few nm.

FIG. 7 is illustrative of an array of DFB lasers with varying grating periods and grating phases. A first laser has a grating 80 with a first grating period and a first grating phase. A second laser has a grating 82 with a grating period greater than the first grating period and a grating phase the same as the first grating phase. A third laser has a grating 84 with the first grating period and a grating phase, or longitudinal offset, which differs from the first grating phase. Further embodiments may include gratings which differ in both period and/or phase, or various combinations thereof, from other lasers in an array of lasers. For example, an array of twelve lasers may have with gratings covering every combination of three different periods and four different phases.

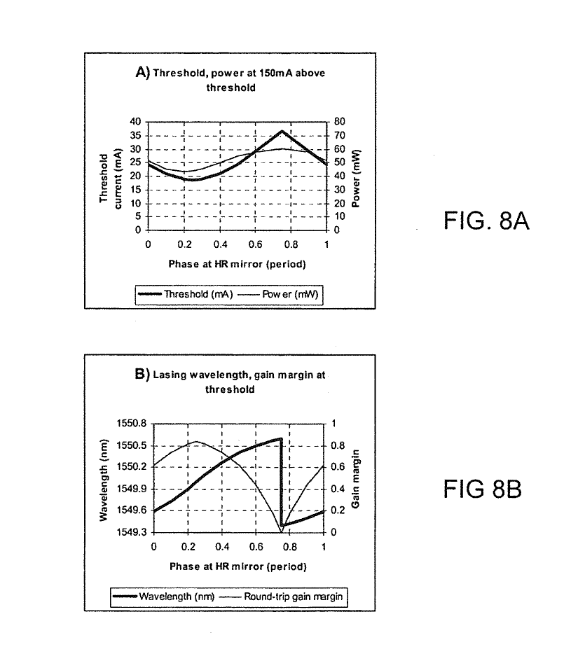

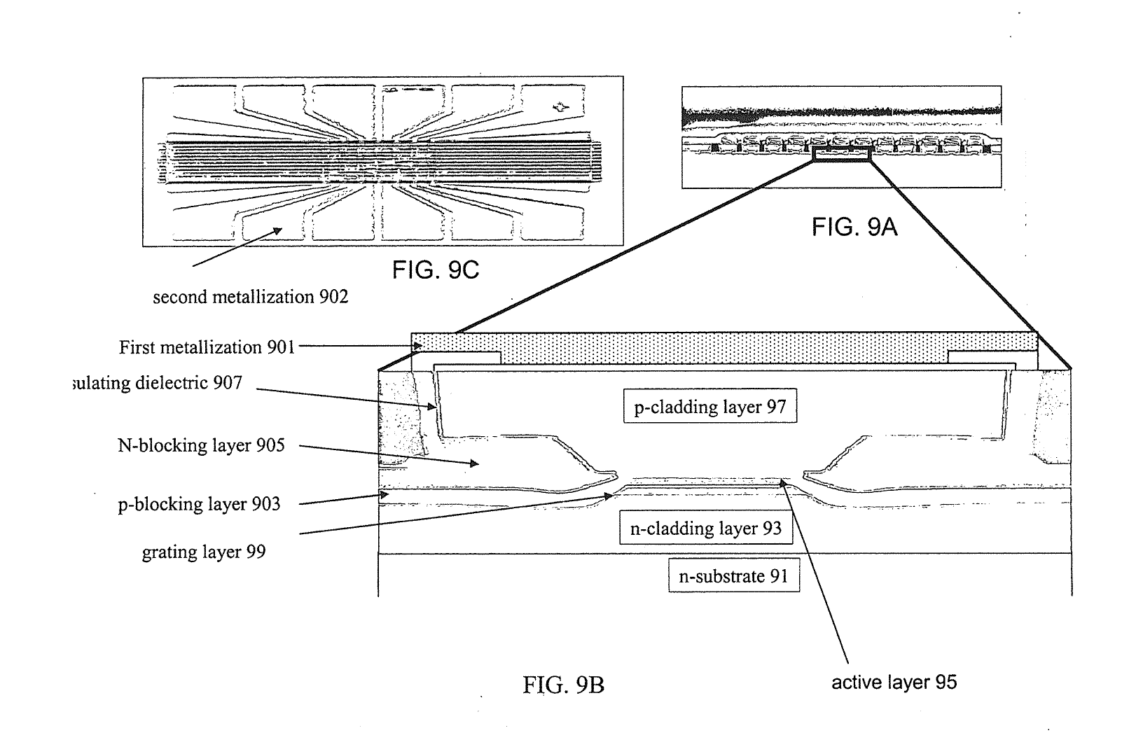

FIGS. 8A and 8B illustrate examples of the effect of controlled grating variations on wavelength and SMSR. FIG. 8A illustrates simulated effect of facet phase in an HR/AR DFB laser on threshold current and output power at 150 mA above threshold as a function of HR facet power. FIG. 8B illustrates simulated effect of facet phase in the same HR/AR DFB laser on lasing wavelength and gain margin. The gain margin represents the degree to which the next lasing wavelength is suppressed, and therefore gives an indication of spectral purity. In this example, the threshold current varies from 19 mA to 37 mA, and the output power from 43 to 60 mW, which may be tolerable variations. However the wavelength varies over a 1 nm range, and there is a range of phases for which the gain margin is very small and the laser is likely to operate with more than one wavelength. In practice roughly half of lasers made in this way will satisfy the spectral purity criteria, and these lasers will exhibit wavelength variations of up to about 1 nm.

In the example of FIGS. 8A and 8B, for each grating period, two of the grating phases would be expected to give spectrally pure lasers, with wavelength separation approximately 0.4 nm. The grating periods are selected to give wavelength separations of approximately 0.8 nm for a given phase. The array therefore provides spectrally-pure operation over a range of about 1.6 nm, with wavelength accuracy of +/−0.2 nm. Typical channel spacings in a wavelength-division-multiplexed (WDM) system are 0.8 nm (100 GHz) and 0.4 nm (50 GHz), with some move to 0.2 nm (25 GHz). This array therefore allows selection of between 3 and 9 channels, with acceptable spectral purity.

FIGS. 9A-9C illustrate various views of a DFB laser array in accordance with aspects of the invention. In this case a buried heterostructure laser is shown. FIG. 9A illustrates an end view of a front facet of the laser array. FIG. 9B illustrates a cross-section view of a laser in the laser array. FIG. 9C illustrates a top view of the laser array. In other embodiments, ridge waveguide, buried rib, or other types of lasers are used. In the laser of FIG. 9B, the laser epitaxial layers are grown on an n-type InP substrate 91. The first layer of the laser is an n-type epitaxially grown InP lower cladding layer 93. Then five strained InGaAsP quantum wells are embedded in a quaternary waveguide, or an active layer, 95. Above the waveguide 95 is a top p-type InP cladding layer 97. In the buried heterostructure configuration, the active layer is patterned, and on either side p-type 903 and n-type 905 blocking regions are grown. The structure is etched in to provide isolation between different elements of the array. For a DFB laser, the growth is interrupted midway and a grating 99 is etched into the laser in this case below the waveguide 95. After the ridge is etched, the wafer is coated with an insulating dielectric 907, such as silicon nitride, with the dielectric removed on top of the ridge to form layer 907. Metallization is applied to the top of the ridge, as shown by element 901. Referring to FIG. 9C, a second metallization 902 provides contact regions. The second metallization is apparent in the top view of the chip.

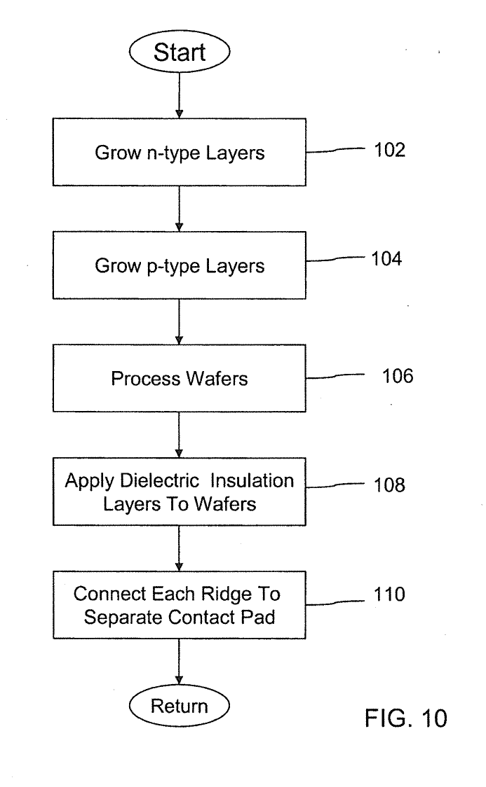

FIG. 10 illustrates a flow diagram of one embodiment of a process of fabricating a DFB laser in accordance with aspects of the invention. In various embodiments, the process applies to single mode laser structures such as buried heterostructure, buried rib or ridge lasers. In block 102, n-type cladding layers are grown in one epitaxial step with metal-organic chemical vapor (MOCVD) deposition. Above the n-type cladding layers, quantum wells are strained to increase the available gain at a desired operating wavelength of 1550 nm. A waveguide surrounding the quantum wells and a grating layer are made from a quaternary composition of InGaAsP that is transparent at the lasing wavelength, for example, having an intrinsic photoluminescence peak of 1100 nm. After the first epitaxial growth, the wafer is covered with a resist suitable for electron beam lithography, and grating structures are exposed, developed, and etched into the layer. In block 104, the wafer is placed back in the MOCVD reactor and a p-type top cladding layer containing an etch-stop is grown and topped off with an InGaAs contact layer. In block 106, the wafer is processed by etching 4 micron ridges above the gratings, stopping at the etch-stop layer. In block 108, dielectric insulation layer is applied to the surface of the wafer, and windows are opened on top of the ridge. In block 110, the ridges are then metallized in such a fashion that each ridge is connected to a separate contact pad. Two layers of metal are used with an additional dielectric layer in between.

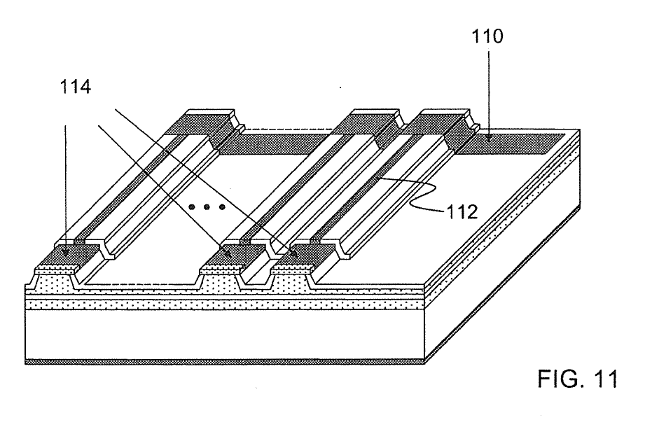

In some embodiments integrated heaters are combined with the laser array to provide an additional variable to control the wavelength. This may reduce any need for a thermoelectric controller, and therefore reduce the cost of the laser and simplify the packaging. FIG. 11 illustrates an embodiment of integrated heaters combined with a laser array. Resistive heater stripes are integrated on top of a DFB laser array to adjust the temperature of the stripes themselves. The heater stripes may be, for example, as in U.S. Patent Publication No. US-2002-0090011-A1, the disclosure of which is incorporated herein by reference.

In various embodiments, the invention is used with or as part of single mode laser structures such as buried heterostructure, buried rib or ridge lasers. In one embodiment, the laser is a ridge laser structure with an index grating above the waveguide. The laser contains five strained InGaAsP quantum wells embedded in a quaternary waveguide. Above the waveguide is an InP spacer laser separating the waveguide from an InGaAsP grating layer. Below the waveguide is an n-type cladding layer, and these layers are grown in one epitaxial step with metal-organic chemical vapor (MOCVD) deposition. The quantum wells are strained to increase the available gain at the desired operating wavelength of 1550 nm. The waveguide surrounding the quantum wells and the grating layer are made from a quaternary composition of InGaAsP that is transparent at the lasing wavelength, for example, having an intrinsic photoluminescence peak of 1100 nm. After the first epitaxial growth, the wafer is covered with a resist suitable for electron beam lithography, and grating structures are exposed, developed, and etched into the layer. The wafer is then placed back in the MOCVD reactor and a p-type top cladding layer containing an etch-stop is grown and topped off with an InGaAs contact layer.

The wafer is processed by etching 4 micron ridges above the gratings, stopping at the etch-stop layer. A dielectric insulation layer is applied to the surface of the wafer, and windows are opened on top of the ridge. The ridges are then metallized in such a fashion that each ridge is connected to a separate contact pad. Either single layer of metallization or two layers of metal are used with an additional dielectric layer in between. Though ridge lasers and their design are well known in the art, in this particular embodiment, multiple lasers are fabricated on the same chip, each one is separately contacted, and each one has a different grating buried in the ridge structure.

Referring back to FIG. 11, once the laser array is fabricated, dielectric is deposited on the ridges, and a heater element is formed on top of the ridges. The heater element is formed by contact pads 110 and 114 and a thin connecting layer 112. The contact pads 110 and 114 are connected by the thin connection layer 112 placed longitudinally along ridge. The contact pad 114 is placed on the front of the ridge and contacts the metallization layer. The contact pad 110 is on top of the further dielectric layer, and placed at the rear of the ridge.

In operation, a laser from the laser array is selected and configured to lase at high temperatures. In some embodiments, a laser that has a desired wavelength at a desired temperature is selected. A laser having a particular wavelength and operating temperature is identified by consulting a look-up table. As the case temperature changes, the heating power to the laser is changed to maintain the high temperature and the wavelength of the laser.

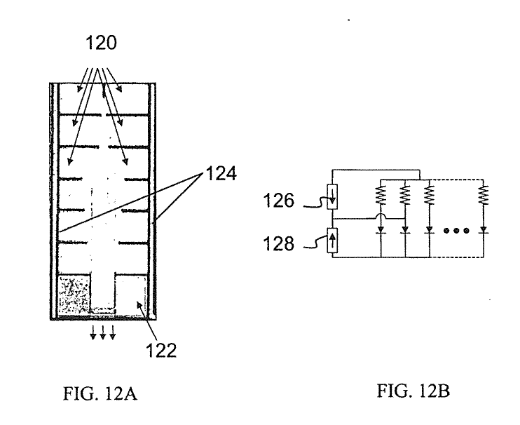

FIG. 12A illustrates a top-view of another embodiment of a DFB laser array with heater elements. A plurality of laser contacts 120 are connected to a heater contact 122 via thin connecting layers 124. FIG. 12B illustrates an electrical schematic of the DFB laser array with heater elements of FIG. 12A. In this embodiment, laser current 128 provides current to the laser diodes to activate the lasers on the chip. In the same embodiment, heater current 126 produces a reverse bias on the laser diodes that are not selected, causing heating to occur only on the selected laser diode. In some embodiments, although the lasers adjacent to the selected laser are not activated, they are reverse biased by the heater current 126 to further increase the heating of the selected laser.

In some embodiments, once such an array is fabricated, the lasers are tested for wavelength at a particular temperature, and one of the lasers is selected. For example, if the application specifies that the wavelength of the laser be 1550.0 nm at a maximum operating temperature of 70 C, the laser element whose wavelength of 1550 is achieved at a temperature closest but above 70 C is selected. The heater is then biased to maintain this temperature or wavelength by implementing control loops as the case temperature is varied.

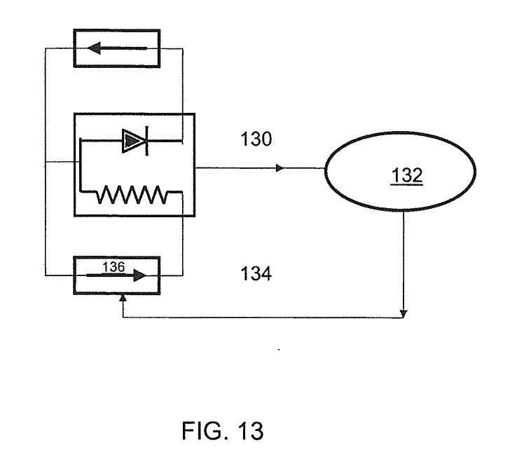

FIG. 13 illustrates an embodiment of controlling heater power of a DFB laser array. In this embodiment, the optical beam from the laser 130 enters a wavelength locker 132, and an error signal 134 is generated by the locker 132 that is proportional to the difference between the desired wavelength and the operating wavelength. The heater power 136 is adjusted accordingly to minimize this error in a conventional negative feedback control loop.

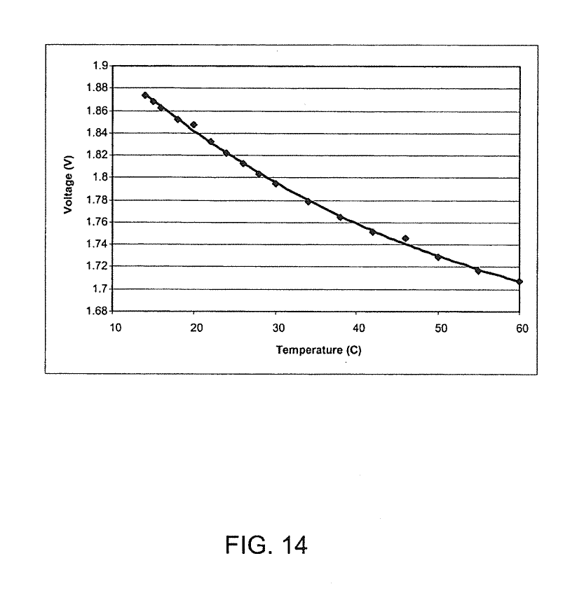

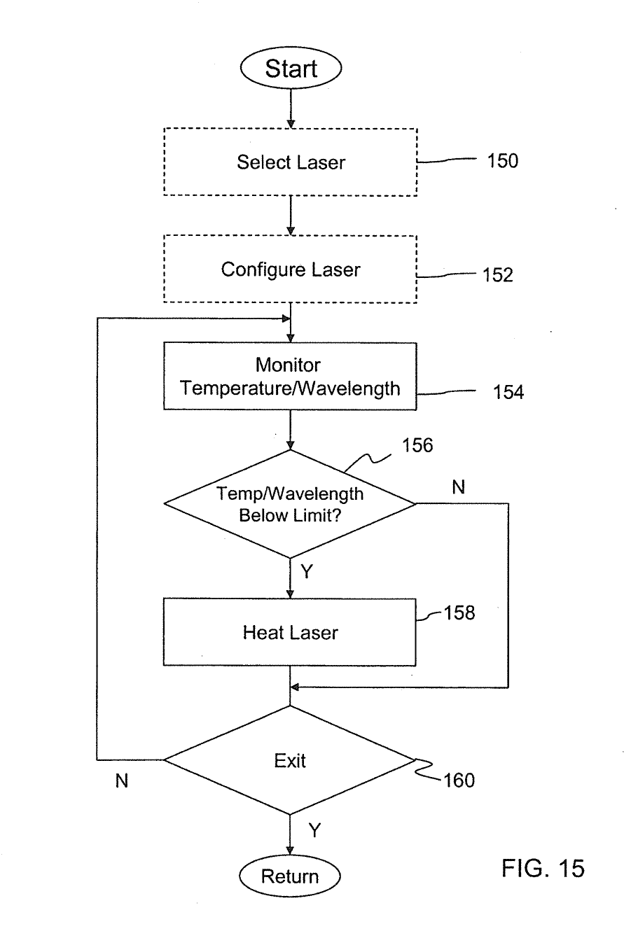

In another embodiment, instead of a wavelength locker, the heater current is adjusted to maintain a constant calibrated diode voltage. This embodiment keeps the diode temperature constant and consequently stabilizes the wavelength. FIG. 14 shows the voltage on a DFB laser as a function of temperature. As the diode temperature increases, the bandgap of the semiconductor decreases and the diode voltage drops. The relationship between the two is roughly 40 mV voltage drop for every 10 degrees C., or 1 nm of wavelength change. Thus to stabilize the DFB wavelength to 0.1 nm, roughly the intrinsic wavelength stability of DFB lasers, the electronics should stabilize the diode voltage to about 4 mV. This is relatively simple with low pass filters, as the time constants need not be excessively fast.

In yet another embodiment, the DFB laser package is characterized to accurately measure the thermal resistance of the laser. Then by monitoring the case temperature, the heater power is adjusted to maintain constant laser temperature. For example, if the laser thermal resistance is 100 C/watt, and the case temperature is measured by a thermostat to be 20 C, when the desired laser temperature is 70 C, 0.5 watts of heater power is applied.

There are various trade-offs in the design of such a laser. There are various factors that improve the overall power consumption of the module. Some simple factors include reducing the total temperature span where the laser needs to be stabilized. The heater maintains the laser temperature above the maximum case temperature in some embodiments, thus low case temperatures consume more electrical power. Another factor is increasing the efficiency of the laser. Since the laser itself uses electrical power to generate the light, the junction temperature will generally be higher than the case temperature. The difference is related to the thermal resistance of the diode. Increasing the thermal resistance lowers the required heater power, but also increases the junction temperature. This increase in the junction temperature is proportional to the electrical power consumed by the laser to generate light, thus a more efficient laser enables increased thermal resistance which reduces the heater power.

A numerical example is a laser diode that requires 110 mA at 1.5V at 90 C junction temperature to generate 10 mW of output power. The diode is required to operate at a case temperature of −5 C to 70 C. Since the difference between the junction temperature and the maximum operating temperature is 20 C, and the power consumed by the diode is 0.165 W, the chip and packaged are designed to have a thermal resistance of 20/0.165=121 C/watt. Thus at 70 C the extra heater power required is zero, while at −5 C, the extra heater power is 0.62 watts (desired junction temperature−minimum case temperature)/thermal resistance−laser power consumption.

FIG. 15 illustrates a flow diagram of one embodiment of a process of controlling wavelength of a laser array in accordance with aspects of the invention. In various embodiments, the process applies to single mode laser structures such as buried heterostructure, buried rib or ridge lasers. In optional block 150, a laser may optionally be selected from a laser array. Preferably, the selected laser meets the desired wavelength but operates closely above the desired maximum operating temperature. In optional block 152 of the process, the selected laser may be operationally configured to lase light. For example, current is applied to the selected laser and reverse bias current is provided to the lasers that are not selected, thus causing heating to occur for the selected laser. In block 154 of the process, the temperature and/or wavelength of the selected laser is monitored. In block 156 of the process, the process checks if the temperature and/or the wavelength of the selected laser is below the desired operating temperature and/or the wavelength. In some embodiments temperature is monitored by way of a temperature sensitive element, for example a thermistor, mounted to or about the laser packaging. In other embodiments temperature is monitored indirectly by way of monitoring the output wavelength of the laser, for example using a wavelength locker. If below the desired temperature, then in block 158 the process heats the laser, preferably to a temperature close to, and preferably above, a specified maximum operating temperature. In one embodiment, heat may be provided to the laser continuously. In some other embodiments, heat may be provided as pulses. In block 160 the process determines if the process should exit. If so, the process exits, otherwise the process goes to block 154.

In some embodiments in accordance with aspects of the invention, an electro-absorption modulator (EA) is integrated on the same chip as a DFB laser to receive light from the laser and to provide on-board modulation of the light. The electro-absorption modulator is reverse biased to change the transmission through it and thus modulate the light of the DFB. Usually, the bandgap in the EA is above that of the laser, so at zero bias much of the light is transmitted. As the voltage increases on the EA, the bandgap shifts to lower energies either through the Franz-Keldysh effect or the Quantum Confined Stark Effect depending on whether the active material is composed of bulk or quantum wells respectively. Unfortunately, since the DFB wavelength should be just below the bandgap of the EA, the operating point should be maintained as the temperature is varied. In quantum well material, the wavelength should typically be matched to within 4 nm, while in bulk, it should be matched to about 15 nm. As the temperature of the chip changes, the DFB wavelength changes at about 0.1 nm/C, while the EA bandgap changes at about 0.5 nm/C. Thus over the typical environmental temperature range of −5 C to 85 C, the mismatch between the two sections varies by (0.5−0.1)*(85−−5)=36 nm, far in excess of the allowable limits. Thus many commercially available EMLs are packaged with thermo-electric coolers to maintain the match between the DFB and the EA.

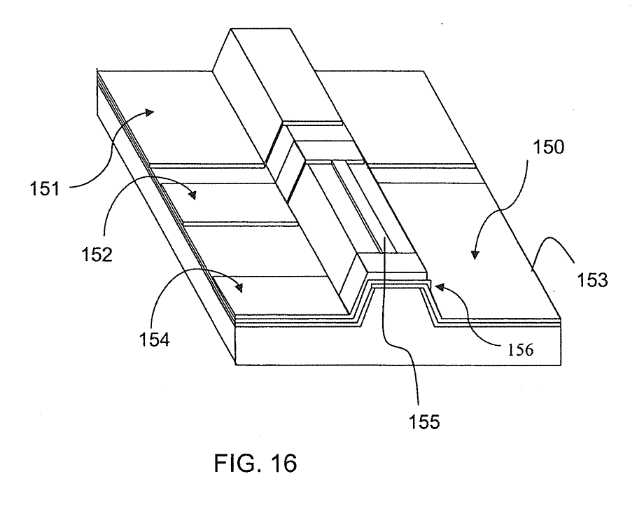

Some embodiments are implemented with considerably less electrical power to realize a laser with a constant wavelength, or an EML with proper matching. FIG. 16 illustrates an embodiment of an EML with a heater. The EML includes a DFB 151 and an electroabsorption modulator 153. Light from the DFB passes into the electroabsorption modulator which modulates the light in accordance with an input signal to the modulator. The input signal to the modulator is provided by way of an EA contact 150. Reverse biasing the modulator using the input signal modulates the light from the DFB.

In the embodiment of FIG. 16, a heater is placed only on the modulator section of the chip. In the embodiment, the heater is a resistive heater 155 placed along the modulator section, with a dielectric, or passivation layer, 156 providing electrical insulation between the resistive heater and the modulator. Current is passed through the resistive heater through application of a heater current by way of heater contact pads 152 and 154. A second passivation layer 156 on the EA section isolates the heater from the main EA contact 150. Thus, the EA contact 150 electrode may be reverse biased to modulate the light coming from the DFB section, while the heater current is varied to maintain the proper wavelength registration between the DFB and the EA.

In some embodiments, the device is stabilized by monitoring the case temperature and varying the heater current accordingly. For example, the thermal resistance of a short 200 micron EA section is 100 C/Watt of heat, and the EA and DFB maintain optimal registration at the high case temperature of 75 C. The maximum detuning acceptable between the DFB and the EA is 6 nm from this optimal setpoint. Furthermore, assume that the DFB tunes at 0.1 nm/C, while the EA tunes at 0.4 nm/C. Thus the two sections of the device detune from each other at 0.3 nm/C. Since there is a 6 nm window, no heater power is required to maintain acceptable registration until the temperature falls below 55 C, at which point, the control would provide a heater power of 7.5 mW/C to the EA section. The 7.5 mW value is simply the relative detuning (0.3 nm/C) divided by how fast the EA tunes (0.4 nm/C), all divided by the thermal resistance. At the temperature setting of −5 C case, a total heater power of 450 mW is used.

In some embodiments, both front and back power of the laser are monitored. The laser current is adjusted according to the back power since the back power measures the laser output power. The heater is adjusted based on the front power, since the front power is a measure of the EA's bandgap.

For both the EA and the DFB, some steps can be taken to increase the thermal resistance of the device in order to reduce the heater power. For example quaternary layers of InGaAsP which have a low thermal conductivity are buried below the waveguide in order to increase the thermal resistance in some embodiments. Furthermore, trenches are etched around the waveguide to reduce the lateral heat flow in some embodiments.

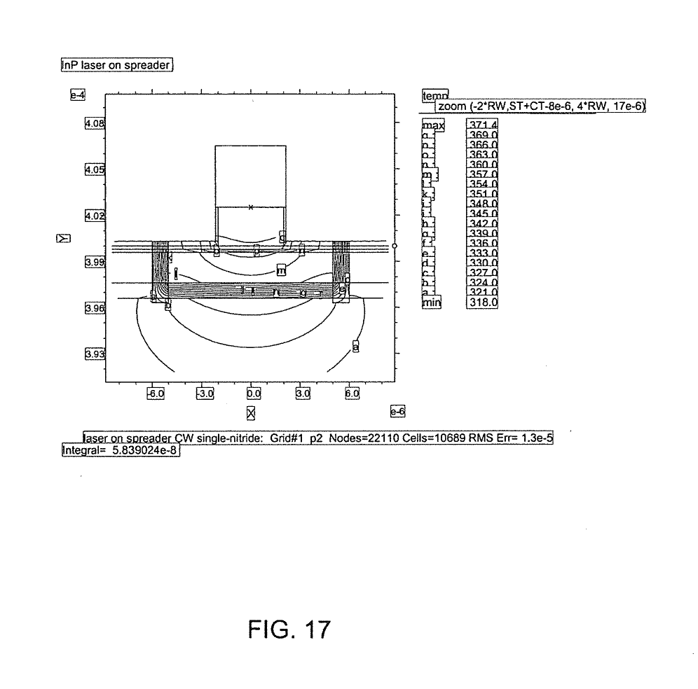

FIG. 17 illustrates a calculation of the temperature profile in a ridge waveguide laser containing both a buried quaternary layer and trenches to obtain a thermal resistance of about 80 C/Watt.

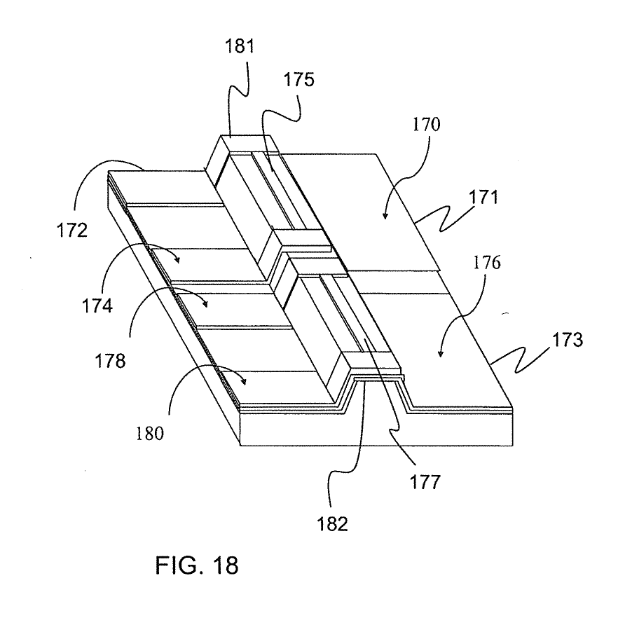

FIG. 18 illustrates an embodiment in which both a DFB laser and an EML have separate integrated heaters. As with the device of FIG. 16, a DFB 171 and an electroabsorption modulator 173 are integrated on a chip. The electroabsorption modulator receives light from the DFB and modulates the light. A DFB contact pad 170 allows for provision of a lasing signal to the DFB. An EA contact pad 176 allows for provision of a modulation signal to the EA.

The DFB includes a heater 175. The electroabsorption modulator includes a heater 177. As illustrated, both the heater 175 and the heater 177 are resistive heaters. A signal is provided to the DFB heater by way of DFB heater contact pads 172 and 174. A signal is provided to the EA heater by way of EA heater contact pads 178 and 180. Passivation layers 181 and 182 isolate the heater contact pads from the lasing and modulation contact pads, respectively. Thus, the DFB heater pads 172 and 174 provide direct control of the DFB temperature and the EA heater pads 178 and 180 provide direct control of the modulator temperature. In various embodiments the device of FIG. 18 is implemented as an array of lasers and corresponding modulators.

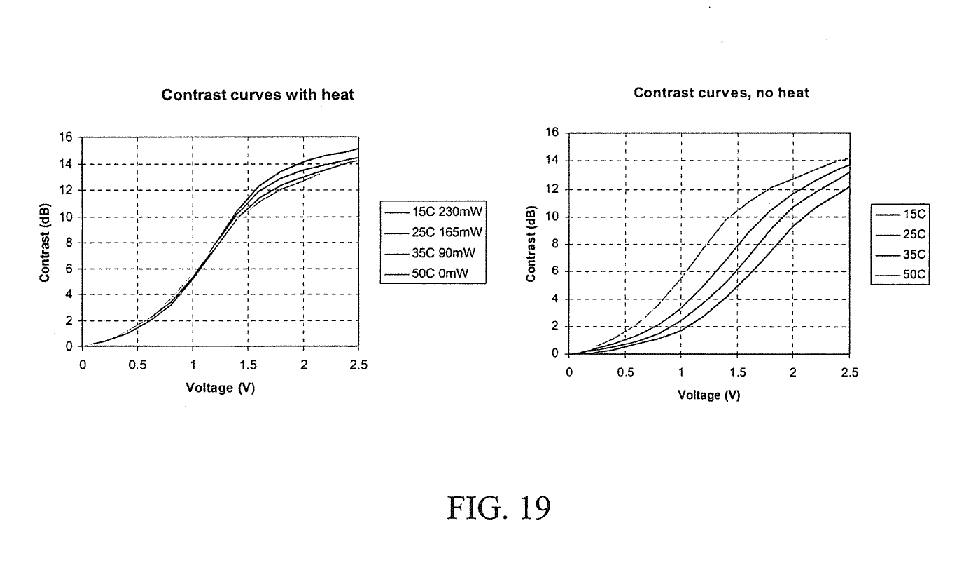

FIG. 19 shows measured results on an electroabsorption modulated laser with a heater only on the modulator to control the wavelength registration between the laser and the modulator as the external temperature changes. As previously mentioned, this generally obviates the need for a thermoelectric controller to keep the operation of the device constant. The first part of the figure shows that as the temperature changes, the operation of the device changes, thus the contrast is greater at 50 C than it is at 15 C. The reason is that at higher temperature the bandgap of the modulator shrinks considerably, while the lasing frequency of the DFB laser drops only slightly. Thus the correspondence between the two sections of the device changes as a function of temperature. In FIG. 19 only the contrast as a function of voltage is shown, but other properties of the device also change with temperature. For example, the chirp of the device, often critical for long distance transmission through dispersive fiber, would also change dramatically as a function of temperature. In the second plot of the figure, the heater power to the modulator is adjusted to compensate for changes in the device. By adjusting the heater power, proper registration between the laser and the modulator is maintained, and thus the operation of the device is constant between 15 C and 50 C. One would expect that other properties of the device, such as the chirp would also remain constant. Though FIG. 19 shows only a single element, arrays of such devices can be fabricated in order to increase yields and reduce inventory needs, as described previously.

Accordingly, the present invention provides a system and methodology for providing a DFB laser array with wavelength accuracy and spectral purity. The present invention also provides system and methodology for integrating heaters to DFBs and EMLS. Although this invention has been described in certain specific embodiments, many additional modifications and variations would be apparent to one skilled in the art. It is therefore to be understood that this invention may be practiced otherwise than is specifically described. Thus, the present embodiments of the invention should be considered in all respects as illustrative and not restrictive. The scope of the invention to be indicated by the appended claims, their equivalents, and claims and their equivalents supported by the specification rather than the foregoing description.

1. An increased yield distributed feedback (DFB) laser device, comprising:
a plurality of DFB lasers on a chip, each of the DFB lasers capable of lasing light, the light having spectral characteristics depending at least in part on a grating forming part of each DFB laser, wherein each grating differs by a controlled grating variation, and wherein the chip is mounted on a submount, the submount including only one bond pad thereon for receiving an electrical coupling from the DFB lasers, and only one DFB laser is electrically coupled to the one bond pad such that only the one DFB laser is operationally configured to lase light.

2. The increased yield DFB device of claim 1 wherein the controlled grating variation comprises a variation in phase.

3. The increased yield DFB device of claim 2 wherein each grating has substantially the same period.

4. The increased yield DFB device of claim 3 wherein each grating has the same period.

5. The increased yield DFB device of claim 1 wherein the controlled grating variation comprises a variation in grating period.

6. The increased yield DFB device of claim 1 wherein the controlled grating variation comprises a variation in phase and grating period.

7. The increased yield DFB device of claim 1 wherein each of the DFB lasers is configured to lase light approximate the same wavelength.

8. The increased yield DFB device of claim 1 wherein the single DFB operationally configured to lase light is a DFB laser meeting predetermined spectral specifications.

9-45. (canceled)
